(19) United States
(12) Patent Application Publication
(10) Pub. No.: US 2019/0372050 A1
(43) Pub. Date: Dec. 5, 2019

(54) LIGHT EMITTING DEVICE

(71) Applicant: PIONEER CORPORATION, Bunkyo-ku, Tokyo (JP)

(72) Inventors: Ayako YOSHIDA, Bunkyo-ku, Tokyo (JP); Takeru OKADA, Bunkyo-ku, Tokyo (JP); Takashi CHUMAN, Bunkyo-ku, Tokyo (JP)

(21) Appl. No.: 16/485,373

(22) PCT Filed: Feb. 9, 2018
(86) PCT No.: PCT/JP2018/004522

§ 371 Date: Aug. 12, 2019

(30) Foreign Application Priority Data
Feb. 17, 2017 (JP) 2017-027600

(51) Int. Cl. H01L 51/52; F21S 43/19; F21S 43/145

(52) U.S. Cl. CPC H01L 51/5203; F21S 43/195; H01L 51/5209; H01L 51/5225; H01L 51/56; H01L 2251/5338; H01L 2251/558; H01L 51/5253; F21S 43/145

(57) ABSTRACT

A light emitting device (10) includes a light emitting portion (140), a first terminal (203), a second terminal (204), a first interconnect (191), and a second interconnect (192). The light emitting portion (140) is disposed on a first surface (101) side of a substrate (100), and has a laminated structure including a first electrode (110), an organic layer (120), and a second electrode (130). The first terminal (203) is disposed over a first end portion (103) of the substrate (100), and is electrically connected to the first electrode (110) or the second electrode (130). The second terminal (204) is disposed over a second end portion (104) of the substrate (100) facing the first end portion (103), and is connected to the first electrode (110) or the second electrode (130). The first interconnect (191) is connected to the first terminal (203) so as to extend in a direction different from a direction toward the second end portion (104). The second interconnect (192) is connected to the second terminal (204) so as to extend in a direction different from a direction toward the first end portion (103).

### TECHNICAL FIELD

The present invention is related to a light emitting device.

### BACKGROUND ART

In recent years, light emitting devices using an organic EL have been developed. The light emitting devices are used as lighting devices or display devices, and have configurations in which an organic layer is interposed between a first electrode and a second electrode. The organic EL can be, for example, thin, flexible, surface light emission, or the like, and can be applied to various designs.

Patent Document 1 discloses a heart-shaped or star-shaped organic EL light emitting device. It is described that a positive electrode contact portion and a negative electrode contact portion are provided separately from each other.

### RELATED DOCUMENT

### Patent Document

[Patent Document 1] Japanese Unexamined Patent Publication No. 2016-26376

### SUMMARY OF THE INVENTION

### Technical Problem

In order to control the organic EL, for example, a cable interconnect is connected to terminals of a positive electrode and a negative electrode. However, in a case of connecting a plurality of cable interconnects, there is a possibility that the cable interconnects spatially interfere with each other, and there is a possibility that a degree of freedom in design is impaired.

As one example of the problem to be solved by the present invention, by preventing the interference of the cable interconnects, the degree of freedom in design of an organic EL device is increased.

### Solution to Problem

According to the invention described in claim 1, there is provided a light emitting device including: a light emitting portion which is disposed on a first surface side of a substrate and has a laminated structure including a first electrode, an organic layer, and a second electrode; a first terminal which is disposed over a first end portion of the substrate and is electrically connected to the first electrode or the second electrode; a second terminal which is disposed over a second end portion, facing the first end portion, of the substrate and is connected to the first electrode or the second electrode; a first interconnect which is connected to the first terminal to extend in a direction different from a direction toward the second end portion; and a second interconnect which is connected to the second terminal to extend in a direction different from a direction toward the first end portion.

### BRIEF DESCRIPTION OF THE DRAWINGS

The above objects and other objects, features and advantages will become more apparent from the following description of the preferred embodiments and the accompanying drawings.

FIG. 1 is a cross-sectional view illustrating a configuration of a light emitting device according to an example embodiment.

FIG. 2 is a plan view illustrating the configuration of the light emitting device according to the example embodiment.

FIG. 3 is a cross-sectional view illustrating a configuration of a light emitting portion of the light emitting device according to the example embodiment.

FIG. 4 is a cross-sectional view illustrating a modification example of the light emitting device according to the example embodiment.

FIG. 5 is a cross-sectional view illustrating a configuration of a light emitting device according to Example 1.

FIG. 6 is a perspective view illustrating a structure of a vicinity of a second end portion of the light emitting device according to Example 1.

FIG. 7 is a plan view illustrating a configuration of a light emitting device according to Example 2.

FIG. 8 is another plan view illustrating the configuration of the light emitting device according to Example 2.

FIG. 9 is still another plan view illustrating the configuration of the light emitting device according to Example 2.

FIG. 10 is still another plan view illustrating the configuration of the light emitting device according to Example 2.

### DESCRIPTION OF EMBODIMENTS

Hereinafter, example embodiments according to the present invention will be described by using the drawings. In all of the drawings, the same components are denoted by the same reference numerals, and description thereof is not repeated as appropriate.

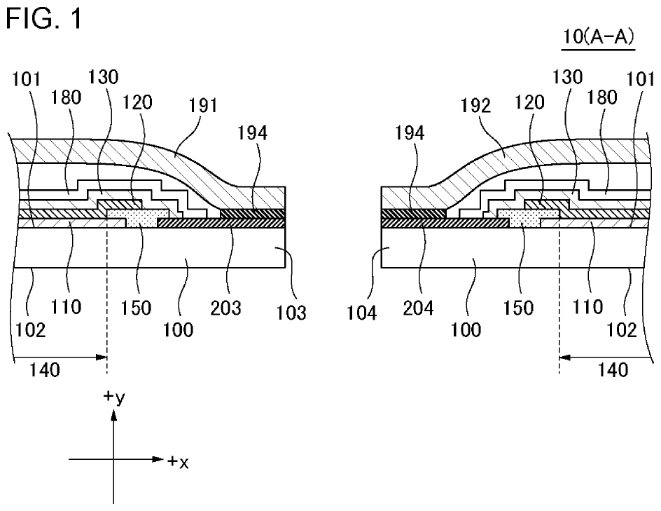

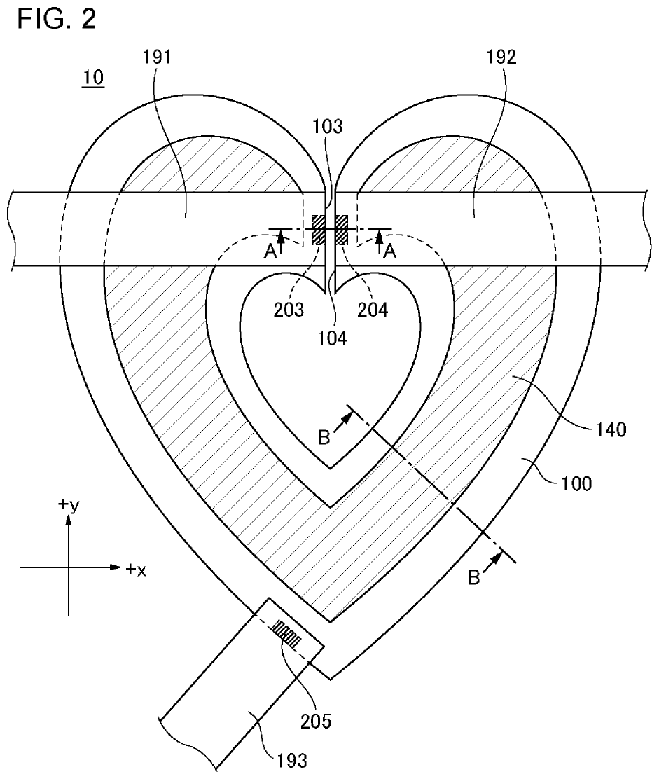

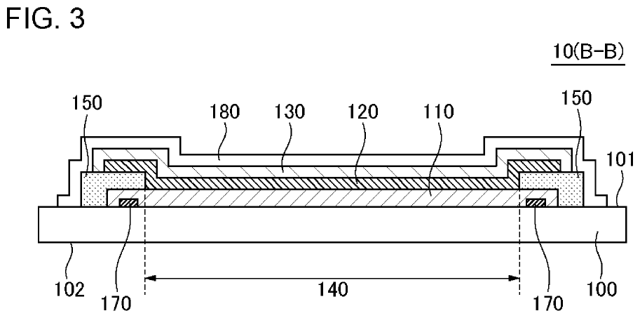

FIG. 1 is a cross-sectional view illustrating a configuration of a light emitting device 10 according to an example embodiment. FIG. 2 is a plan view illustrating the configuration of the light emitting device 10 according to the present example embodiment. FIG. 3 is a cross-sectional view illustrating a configuration of a light emitting portion 140 of the light emitting device 10 according to the present example embodiment. FIG. 1 is a cross-sectional view taken along a line A-A in FIG. 2, and FIG. 3 is a cross-sectional view taken along a line B-B in FIG. 2.

The light emitting device 10 includes the light emitting portion 140, a first terminal 203, a second terminal 204, a first interconnect 191, and a second interconnect 192. The light emitting portion 140 is disposed on a first surface 101 side of a substrate 100, and has a laminated structure including a first electrode 110, an organic layer 120, and a second electrode 130. The first terminal 203 is disposed over a first end portion 103 of the substrate 100, and is electrically connected to the first electrode 110 or the second electrode 130. The second terminal 204 is disposed over a second end portion 104, facing the first end portion 103, of the substrate 100, and is connected to the first electrode 110 or the second electrode 130. The first interconnect 191 is connected to the first terminal 203 so as to extend in a direction different from a direction toward the second end portion 104. The second interconnect 192 is connected to the second terminal 204 so as to extend in a direction different from a direction toward the first end portion 103. Details will be described below.

The light emitting device 10 is a lighting device or a display device. The light emitting device 10 may be attached to a vehicle, for example, and may be used as a brake lamp or the like.

In the light emitting device 10 of the present example embodiment, the first interconnect 191 is provided so as to extend in a direction different from a direction toward the second end portion 104, and the second interconnect 192 is provided so as to extend in a direction different from a direction toward the first end portion 103. Therefore, even in a design in which terminals are provided at the first end portion 103 and the second end portion 104 facing each other, the first interconnect 191 and the second interconnect 192 do not spatially interfere with each other.

Although a material of the substrate 100 is not particularly limited, the substrate 100 is a light-transmissive substrate such as a glass substrate, a resin substrate, or the like, for example. The substrate 100 may have flexibility. In a case where the substrate 100 has flexibility, a thickness of the substrate 100 is equal to or more than 10 μm and is equal to or less than 1000 μm, for example. A shape of the substrate 100 is not particularly limited as long as the substrate 100 has the first end portion 103 and the second end portion 104 facing each other, and may be, for example, a polygon such as a rectangle or a circle as a whole. In a case where the substrate 100 is a resin substrate, the substrate 100 is formed by using, for example, polyethylene naphthalate (PEN), polyether sulfone (PES), polyethylene terephthalate (PET), polyimide, polycarbonate (PC), or an olefin resin. The substrate 100 may be an inorganic-organic hybrid substrate in which an inorganic material and an organic material are combined. In a case where the substrate 100 is a resin substrate, it is preferable that an inorganic barrier film is formed over at least one surface (preferably both of surfaces) of the substrate 100 so as to prevent moisture from passing through the substrate 100. An example of the inorganic barrier film includes a SiNₓ film, a SiON film, a silicon oxide film such as SiOₓ, SiOC, and SiOCN, an alumina oxide film such as Al₂O₃, a titanium oxide film such as TiO₂, a ZTO film, or a combination thereof. The substrate 100 may have a flat shape, or the first surface 101 may be curved.

The light emitting portion 140 is formed over the first surface 101 of the substrate 100. The light emitting portion 140 has a laminated structure in which the light-transmissive first electrode 110, the organic layer 120, and the light-shielding second electrode 130 are stacked in this order. The first electrode 110 is disposed between the substrate 100 and the second electrode 130. Therefore, among light beams emitted from the light emitting portion 140, a light beam output to the first electrode 110 side has a higher intensity than a light beam output to the second electrode 130 side. That is, a second surface 102 opposite to the first surface 101 of the substrate 100 is a light emitting surface.

The first electrode 110 is a transparent electrode having a light-transmission property. A material of the transparent electrode is a material containing metal, for example, a metal oxide such as indium tin oxide (ITO), indium zinc oxide (IZO), indium tungsten zinc oxide (IWZO), zinc oxide (Zn0), or the like. A thickness of the first electrode 110 is equal to or more than 10 nm and is equal to or less than 500 nm, for example. The first electrode 110 is formed by using, for example, a sputtering method or a vapor deposition method. Note that, the first electrode 110 may be a carbon nanotube or a conductive organic material such as PEDOT/PSS.

The organic layer 120 has a light emitting layer. The organic layer 120 has, for example, a configuration in which a hole injection layer, a light emitting layer, and an electron injection layer are stacked in this order. A hole transport layer may be formed between the hole injection layer and the light emitting layer. In addition, an electron transport layer may be formed between the light emitting layer and the electron injection layer. The organic layer 120 may be formed by a vapor deposition method. In addition, at least one layer of the organic layer 120, for example, a layer in contact with the first electrode 110 may be formed by a coating method such as an inkjet method, a printing method, a spray method, or the like. Note that, in this case, the remaining layers of the organic layer 120 may be formed by a vapor deposition method, and all of layers of the organic layer 120 may be formed by using the coating method. All of the layers of the organic layer 120 may be formed by using a vapor deposition method.

The second electrode 130 includes a metal layer made of, for example, a metal selected from a group of Al, Au, Ag, Pt, Mg, Sn, Zn, and In, or an alloy of metals selected from this group. In this case, the second electrode 130 has a light-shielding property. A thickness of the second electrode 130 is equal to or more than 10 nm and is equal to or less than 500 nm, for example. The second electrode 130 is formed by using, for example, a sputtering method or a vapor deposition method. In the example illustrated in FIG. 3, the second electrode 130 is wider than the first electrode 110. For this reason, when seen in a direction perpendicular to the first surface 101 of the substrate 100, the entire first electrode 110 overlaps the second electrode 130 in a width direction, and is covered by the second electrode 130. Note that, the first electrode 110 may be wider than the second electrode 130, and when seen in a direction perpendicular to the first surface 101 of the substrate 100, the entire second electrode 130 may overlap the first electrode 110 in a width direction.

At least a part of an edge of the first electrode 110 is covered by an insulating film 150. The insulating film 150 is formed of, for example, a photosensitive resin material such as polyimide, and encloses a portion of the first electrode 110 to be the light emitting portion 140. In the example of FIG. 3, when seen in a direction perpendicular to the first surface 101 of the substrate 100, a part of the insulating film 150 protrudes from the second electrode 130 in a width direction. In the example illustrated in FIG. 3, the second electrode 130 is also formed over the insulating film 150. In addition, when seen in a direction perpendicular to the first surface 101 of the substrate 100, a part of the organic layer 120 overlaps the insulating film 150. In the example illustrated in FIGS. 2 and 3, the organic layer 120 is also formed over the insulating film 150.

The light emitting device 10 according to the present example embodiment further includes a sealing film 180. The sealing film 180 is formed so as to cover the entire light emitting portion 140. The light emitting portion 140 is disposed between the sealing film 180 and the substrate 100. As the sealing film 180, for example, an inorganic barrier film such as SiNₓ, SiON, Al₂O₃, TiO₂, SiOₓ, SiOC, SiOCN, or the like, a barrier laminated film including the inorganic barrier film, or a mixed film thereof can be used. These can be formed, for example, by a vacuum deposition method such as a sputtering method, a CVD method, an ALD method, an EB evaporation method, or the like. In the example of FIG. 3, a part of the sealing film 180 is in contact with the first surface 101. Note that, the light emitting device 10 may be sealed by using a plate-shaped sealing member instead of the sealing film 180 or in addition to the sealing film 180. In this case, the sealing member is fixed to the substrate 100 through an adhesive layer. In addition, a desiccant may be inserted between the sealing member and the adhesive.

In the example illustrated in FIG. 3, the light emitting device 10 further includes a conductive portion 170. The conductive portion 170 is in contact with the first electrode 110, and can function as an auxiliary electrode of the first electrode 110. When seen in a direction perpendicular to the first surface 101, the conductive portion 170 is, for example, along an outer periphery of the light emitting portion 140. The conductive portion 170 includes a material having higher conductivity than a material of the first electrode 110. Electrical resistivity of the conductive portion 170 is lower than electrical resistivity of the first electrode 110. The conductive portion 170 includes, for example, a metal selected from a group of Al, Ag, Mo, and an alloy thereof. Specifically, the conductive portion 170 maybe AgPdCu (APC) or the like. In addition, the conductive portion 170 may have a configuration in which a first metal layer such as Mo, Mo alloy, or the like, a second metal layer such as Al, Al alloy, or the like, and a third metal layer such as Mo, Mo alloy, or the like are stacked in this order, for example. At least one of the first terminal 203 and the second terminal 204 may be integrally formed with the conductive portion 170. Note that, in the example in the present diagram, the conductive portion 170 is disposed between the substrate 100 and the first electrode 110, but the conductive portion 170 may be disposed between the first electrode 110 and the insulating film 150.

The substrate 100 has at least one pair of end portions facing each other. That is, the first end portion 103 which is a part of an end portion of the substrate 100 and the second end portion 104 which is another part of the end portion of the substrate 100 different from the first end portion 103 face each other. The first end portion 103 and the second end portion 104 are continuous through the other portion of the substrate 100. Note that, each of the first end portion 103 and the second end portion 104 indicate a range within a predetermined distance from an end surface of the substrate 100. The predetermined distance is, for example, 1 mm. Alternatively, each of the first end portion 103 and the second end portion 104 is between the light emitting portion 140 and an edge of the substrate 100. Note that, a distance between the first end portion 103 and the second end portion 104 is equal to or more than 0.5 mm and is equal to or less than 30 mm, for example. In this case, the first interconnect 191 and the second interconnect 192 easily interfere with each other. In the example illustrated in FIG. 2, the first end portion 103 and the second end portion 104 are parallel to each other. However, without being limited to the present example, the first end portion 103 and the second end portion 104 may be nonparallel.

The first terminal 203 is provided on the first surface 101 side of the first end portion 103, and the second terminal 204 is provided on the first surface 101 side of the second end portion 104. At least apart of the first terminal 203 and the second terminal 204 is disposed outside the sealing film 180. The first terminal 203 is electrically connected to the first electrode 110 or the second electrode 130, and the second terminal 204 is electrically connected to the first electrode 110 or the second electrode 130. Each of a thickness of the first terminal 203 and a thickness of the second terminal 204 is equal to or more than 50 nm and is equal to or less than 10 μm, for example.

Each of the first terminal 203 and the second terminal 204 includes a conductive material. An example of the conductive material includes, for example, a metal selected from a group of Al, Ag, Mo, and an alloy thereof. Specifically, the conductive material may be AgPdCu (APC) or the like. In addition, each of the first terminal 203 and the second terminal 204 may have a configuration in which a first metal layer such as Mo, Mo alloy, or the like, a second metal layer such as Al, Al alloy, or the like, and a third metal layer such as Mo, Mo alloy, or the like are stacked in this order, for example. The first terminal 203 may include the same material as a material included in any one of the first electrode 110 and the second electrode 130. In addition, the second terminal 204 may include the same material as the material included in any one of the first electrode 110 and the second electrode 130. Note that, a material and a configuration of the first terminal 203 may be the same as or different from the material and the configuration of the second terminal 204.

The first interconnect 191 is electrically connected to the first terminal 203, and the second interconnect 192 is electrically connected to the second terminal 204. Specifically, one end of the first interconnect 191 and the first terminal 203 are connected through a connection portion 194, and one end of the second interconnect 192 and the second terminal 204 are connected through the connection portion 194. The connection portion 194 is, for example, an intermetallic compound or an anisotropic adhesive. An example of the intermetallic compound includes solder. Note that, a connector may be attached to each of the first terminal 203 and the first interconnect 191, and the first terminal 203 and the first interconnect 191 may be connected through these connectors. In addition, a connector may be attached to each of the second terminal 204 and the second interconnect 192, and the second terminal 204 and the second interconnect 192 may be connected through these connectors.

Each of the first interconnect 191 and the second interconnect 192 is a flexible cable, for example. Each of the first interconnect 191 and the second interconnect 192 is provided separately from the substrate 100. That is, the first interconnect 191 and the second interconnect 192 are not film interconnects formed on a surface of the substrate 100.

As described above, the first interconnect 191 is connected to the first terminal 203 so as to extend in the direction different from the direction toward the second end portion 104, and the second interconnect 192 is connected to the second terminal 204 so as to extend in the direction different from the direction toward the first end portion 103. Specifically, when seen in a direction perpendicular to the first surface 101, the first end portion 103 and the second end portion 104 face each other in a direction parallel to an x-axis direction. Note that, the x-axis direction is an axial direction parallel to the first surface 101. The second end portion 104 is disposed on a +x direction side as seen from the first end portion 103, and the first end portion 103 is disposed on a −x direction side as seen from the second end portion 104. Here, the first interconnect 191 extends from one end attached to the first terminal 203 toward a direction different from the +x direction. The second interconnect 192 extends from one end attached to the second terminal 204 toward a direction different from the −x direction. In the examples of FIGS. 1 and 2, the first interconnect 191 extends from one end attached to the first terminal 203 toward the −x direction, and the second interconnect 192 extends from one end attached to the second terminal 204 toward the +x direction. However, without being limited to the examples in FIGS. 1 and 2, for example, at least one of the first interconnect 191 and the second interconnect 192 may extend in a y-axis direction perpendicular to the x-axis direction.

Note that, as described above, a state in which the first interconnect 191 is connected to the first terminal 203 so as to extend in a direction different from a direction toward the second end portion 104 means a state in which the first interconnect 191 extends in a direction different from a direction toward the second end portion 104 in a state in which no external force is applied to the first interconnect 191. Specifically, for example, the state means a state in which the first interconnect 191 extends in a direction different from a direction toward the second end portion 104 in a state in which the first interconnect 191 is extended according to an orientation relationship between the first interconnect 191 and the first terminal 203 at a connection portion between the first interconnect 191 and the first terminal 203 without the first interconnect 191 being bent or twisted.

In addition, a state in which the second interconnect 192 is connected to the second terminal 204 so as to extend in a direction different from a direction toward the first end portion 103 means a state in which the second interconnect 192 extends in a direction different from a direction toward the first end portion 103 in a state in which no external force is applied to the second interconnect 192. Specifically, for example, the state means a state in which the second interconnect 192 extends in a direction different from a direction toward the first end portion 103 in a state in which the second interconnect 192 is extended according to an orientation relationship between the second interconnect 192 and the second terminal 204 at a connection portion between the second interconnect 192 and the second terminal 204 without the second interconnect 192 being bent or twisted. Note that, in a case where a connector is attached to the first interconnect 191 or the second interconnect 192, a state in which the first interconnect 191 or the second interconnect 192 are bent or the like in the connector is allowed.

At least one of the first interconnect 191 and the second interconnect 192 overlaps the light emitting portion 140 on an opposite side to a light emitting surface side of the light emitting portion 140. The light emitting portion 140 is disposed between the first interconnect 191 and the substrate 100 at a portion where the first interconnect 191 and the light emitting portion 140 overlap each other. In addition, the light emitting portion 140 is disposed between the second interconnect 192 and the substrate 100 at a portion where the second interconnect 192 and the light emitting portion 140 overlap with each other. Therefore, it is possible to reduce an occupied area of the light emitting device 10.

In the example illustrated in FIG. 1, the first terminal 203 and the second terminal 204 are electrically connected to the same electrode of the first electrode 110 and the second electrode 130. More specifically, both of the first terminal 203 and the second terminal 204 are connected to the second electrode 130. While there is a possibility that a vicinity of the first end portion 103 and a vicinity of the second end portion 104 may be electrically farthest from each other, the first terminal 203 and the second terminal 204 are connected to the same electrode, so that it possible to generally stabilize a potential of the electrode.

In addition, the light emitting device 10 further includes a third terminal 205 which is electrically connected to an electrode different from an electrode, to which the first terminal 203 and the second terminal 204 are electrically connected, of the first electrode 110 and the second electrode 130. By further connecting one end of a third interconnect 193 to the third terminal 205, a voltage can be applied to an electrode not connected to the first terminal 203 and the second terminal 204.

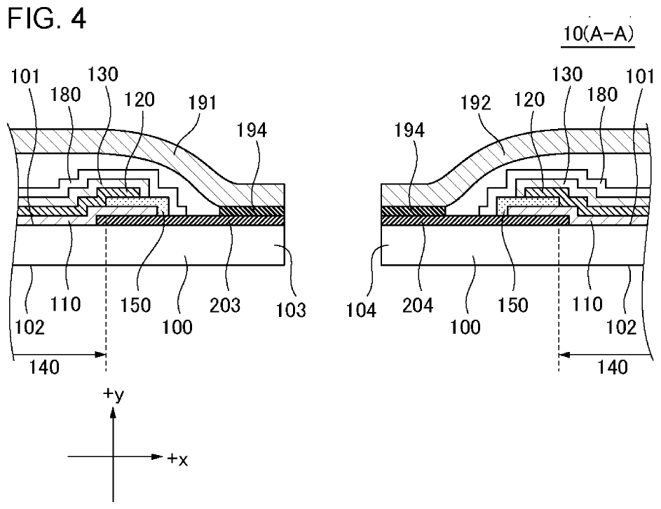

FIG. 4 is a cross-sectional view illustrating a modification example of the light emitting device 10 according to the present example embodiment. The cross-section view illustrated in the present diagram corresponds to the cross section illustrated in FIG. 1. The light emitting device 10 according to the present modification example is the same as the example illustrated in FIG. 1 except that both of the first terminal 203 and the second terminal 204 are connected to the first electrode 110. Conductivity of the transparent electrode may be lower than conductivity of a metal electrode. On the other hand, both of the first terminal 203 and the second terminal 204 are connected to the first electrode 110, so that it possible to generally stabilize a potential of the first electrode 110.

Since the other end of each of the first interconnect 191, the second interconnect 192, and the third interconnect 193 is connected to a control circuit, the first electrode 110 is electrically connected to a positive terminal of the control circuit and the second electrode 130 is electrically connected to a negative terminal of the control circuit.

Next, a manufacturing method of the light emitting device 10 will be described. First, the conductive portion 170 is formed on the substrate 100 by, for example, film formation by a sputtering method or the like and patterning by etching or the like. For example, at this time, it is possible to simultaneously form the first terminal 203, the second terminal 204, and the third terminal 205. Next, the first electrode 110 is formed by using, for example, the sputtering method. Then, the first electrode 110 is formed into a predetermined pattern by using, for example, a photolithography method. Next, the insulating film 150 is formed on the edge of the first electrode 110. For example, in a case where the insulating film 150 is formed of a photosensitive resin, the insulating film 150 is formed into a predetermined pattern through exposure and development steps. Next, the organic layer 120 and the second electrode 130 are formed in this order. In a case where the organic layer 120 includes a layer formed by a vapor deposition method, this layer is formed into a predetermined pattern by using, for example, a mask. The second electrode 130 is also formed into a predetermined pattern by using, for example, a mask. Next, the sealing film 180 is formed so as to seal the light emitting portion 140. After that, the first interconnect 191 is fixed to the first terminal 203, and the second interconnect 192 is fixed to the second terminal 204.

As described above, according to the present example embodiment, the first interconnect 191 is connected to the first terminal 203 so as to extend in a direction different from a direction toward the second end portion 104. The second interconnect 192 is connected to the second terminal 204 so as to extend in a direction different from a direction toward the first end portion 103. Therefore, even in a case where the first end portion 103 and the second end portion 104 face each other, it is possible to prevent the first interconnect 191 and the second interconnect 192 from spatially interfering with each other. As a result, it is possible to increase a degree of freedom in design of the light emitting device 10.

### EXAMPLE 1

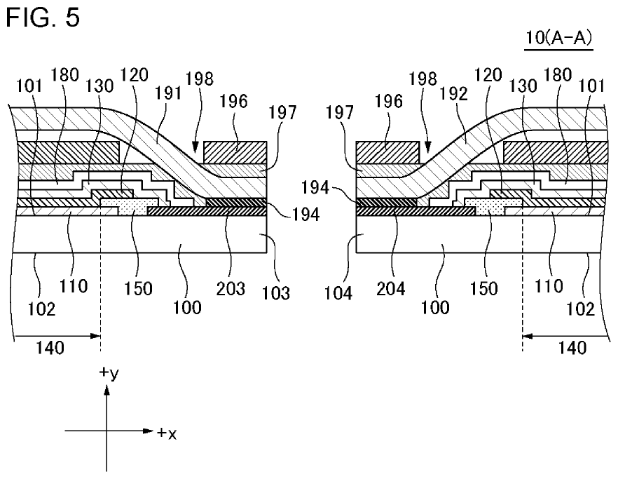

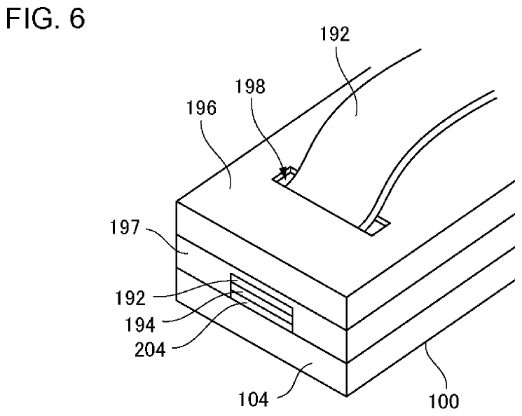

FIG. 5 is a cross-sectional view illustrating a configuration of the light emitting device 10 according to Example 1. In addition, FIG. 6 is a perspective view illustrating a structure of a vicinity of the second end portion 104 of the light emitting device 10 according to Example 1. FIG. 5 corresponds to FIG. 1 of the example embodiment. The light emitting device 10 according to the present example has the same configuration as the light emitting device 10 according to the example embodiment. In addition, the light emitting device 10 according to the present example further includes a fixing member 196 fixed to the substrate 100. At least one of the first interconnect 191 and the second interconnect 192 passes through an opening 198 provided in the fixing member 196. Details will be described below.

The fixing member 196 according to the present example is, for example, a plate-shaped member, and is a resin member. An outer shape of fixing member 196 is, for example, the same as an outer shape of the substrate 100. The fixing member 196 covers at least parts of the light emitting portion 140, the first terminal 203, the second terminal 204, the first interconnect 191, and the second interconnect 192. The fixing member 196 is fixed onto the substrate 100 through an adhesive layer 197. The adhesive layer 197 is, for example, a solidified material or a cured material of an adhesive, and is filled between the light emitting portion 140 and the fixing member 196. Note that, in a case where the adhesive layer 197 and the fixing member 196 have a sufficient sealing function, the light emitting device 10 may not include the sealing film 180.

The fixing member 196 is provided with openings 198 in a vicinity of the first end portion 103 and in a vicinity of the second end portion 104. At least one of the first interconnect 191 and the second interconnect 192 passes through an opening 198. In the example in the present diagram, more specifically, one end, connected to the first end portion 103, of the first interconnect 191 is disposed between the fixing member 196 and the substrate 100. The other end of the first interconnect 191 is disposed on an opposite side to the substrate 100 based on the fixing member 196. In addition, one end, connected to the second end portion 104, of the second interconnect 192 is disposed between the fixing member 196 and the substrate 100. The other end of the second interconnect 192 is disposed on an opposite side to the substrate 100 based on the fixing member 196.

As described above, according to the present example, in the same manner as the example embodiment, the first interconnect 191 is connected to the first terminal 203 so as to extend in a direction different from a direction toward the second end portion 104. The second interconnect 192 is connected to the second terminal 204 so as to extend in a direction different from a direction toward the first end portion 103. Therefore, even in a case where the first end portion 103 and the second end portion 104 face each other, it is possible to prevent the first interconnect 191 and the second interconnect 192 from spatially interfering with each other. As a result, it is possible to increase a degree of freedom in design of the light emitting device 10.

In addition, according to the present example, the light emitting device 10 further includes the fixing member 196, and at least one of the first interconnect 191 and the second interconnect 192 passes through an opening 198 provided in the fixing member 196. Therefore, the light emitting portion 140 or a connection portion between the interconnect and the terminal are protected between the substrate 100 and the fixing member 196, and durability of the light emitting device 10 is enhanced. Further, since the fixing member 196 covers an opposite side to the second surface 102 of the light emitting device 10, a design of a rear surface of the light emitting device 10 is enhanced. In a case where the fixing member 196 is metal, thermal uniformity is further enhanced by high heat dissipation of the fixing member 196. In the light emitting portion 140, since luminance increases as a temperature increases, it is possible to reduce luminance unevenness by enhancing the thermal uniformity.

### EXAMPLE 2

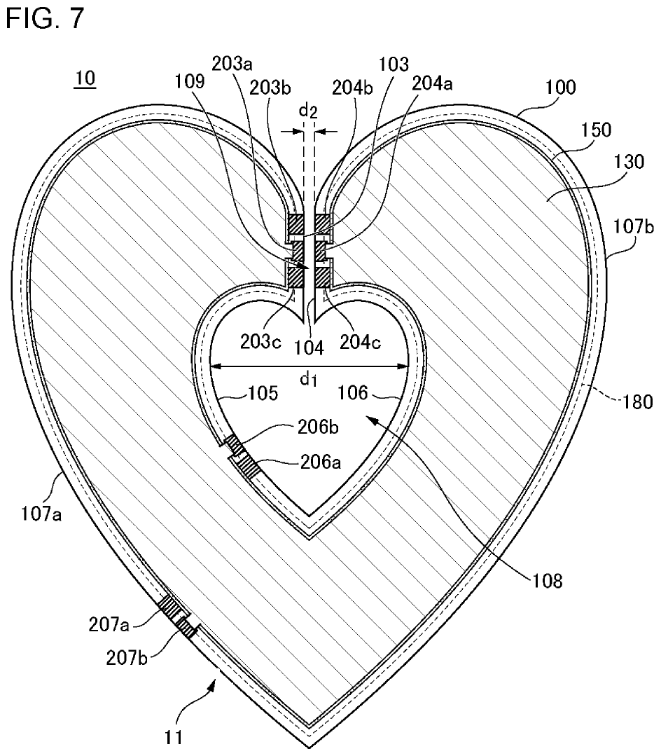

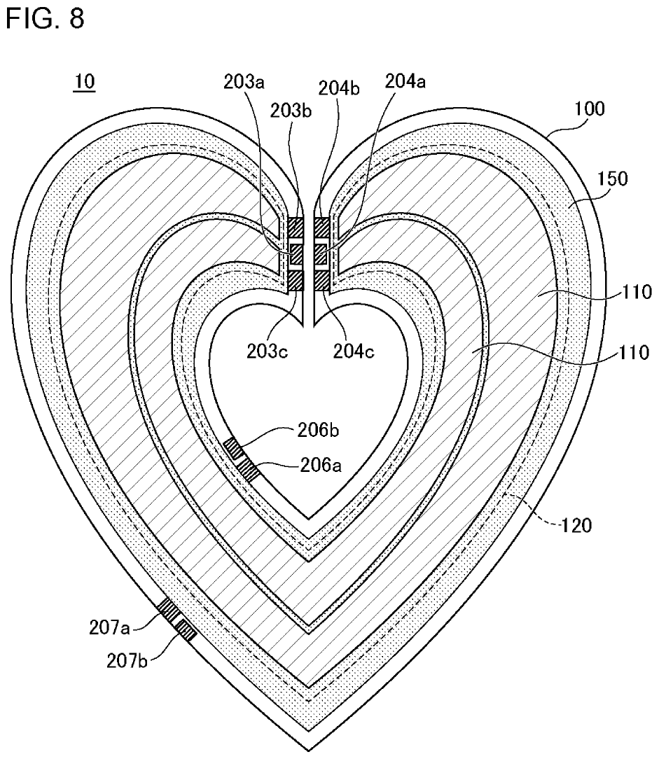

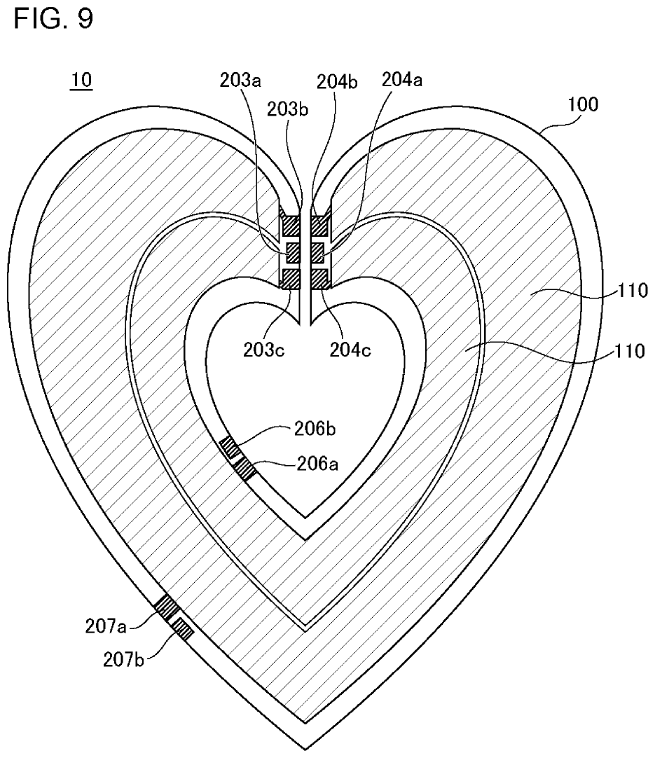

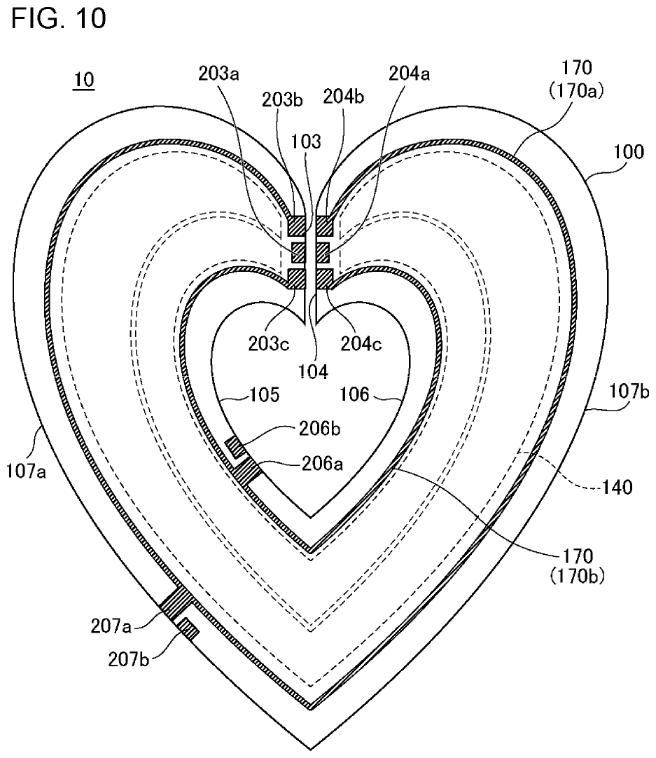

FIGS. 7 to 10 are plan views illustrating a configuration of the light emitting device 10 according to Example 2. FIGS. 7 to 10 illustrate the light emitting device 10 when seen from the first surface 101 side of the substrate 100, that is, from an opposite side to a light emitting surface, and the first interconnect 191, the second interconnect 192, and other interconnects are not illustrated. In FIG. 7, the sealing film 180 is illustrated by a broken line. FIG. 8 is a diagram of FIG. 7 except for the sealing film 180 and the second electrode 130, and an outer periphery of the organic layer 120 is illustrated by a broken line. FIG. 9 is a diagram of FIG. 8 except for the organic layer 120 and the insulating film 150. FIG. 10 is a diagram of FIG. 9 except for the first electrode 110, and an outer periphery of the light emitting portion 140 is illustrated by a broken line. The light emitting device 10 according to the present example has the same configuration as the light emitting device 10 according to at least any one of the example embodiment and Example 1.

In the present example, the substrate 100 surrounds a first area 108 when seen in a direction perpendicular to the substrate 100, the substrate 100 is disconnected in a second area 109 continuous to the first area 108, and the first end portion 103 and the second end portion 104 face each other through the second area 109.

In other words, the second area 109 connects the first area 108 disposed inner side the substrate 100 and an external area 11 disposed outside the substrate 100. Further, in other words, the first area 108 is a hollow portion of the substrate 100, and the second area 109 is a notch portion of the substrate 100.

Further, in the present example, an end portion of the substrate 100 includes the first end portion 103, the second end portion 104, a third end portion 105, a fourth end portion 106, a fifth end portion 107a, and a fifth end portion 107b. A maximum distance between the third end portion 105 and the fourth end portion 106 facing each other through the first area 108 among end portions of the substrate 100 is a first distance d₁. A distance between the first end portion 103 and the second end portion 104 facing each other through the second area 109 among the end portions of the substrate 100 is a second distance d₂. The second distance d₂ is shorter than the first distance d₁.

Further, in the present example, the third end portion 105 and the fifth end portion 107a are continuous along the edge of the substrate 100. Here, the third end portion 105 is one end portion of the substrate 100, and the fourth end portion 106 is an end portion facing the third end portion 105 through the first area 108. The fifth end portion 107a is an end portion on an opposite side to the third end portion 105 of the substrate 100.

As described above, in the light emitting device 10 according to the present example embodiment, the substrate 100 surrounding the first area 108 is disconnected at the second area 109. Therefore, even in a case where the substrate 100 is disposed, for example, along a curved surface, the second area 109 absorbs excess or deficiency of dimension, so that the light emitting device 10 is less likely to be warped or wrinkled. In addition, it is possible to obtain the light emitting device 10 having an excellent design.

In present example, the conductive portion 170 is along the outer periphery of the light emitting portion 140. Therefore, it is possible to supply a sufficient power to the light emitting portion 140, and it is possible to suppress unevenness in light emission.

In addition, in a case of using a mask so as to form the organic layer 120, the second electrode 130, or the like into a predetermined pattern, a support portion which fixes a portion of the mask corresponding to the first area 108 to a deposition apparatus can be overlapped with the second area 109. Therefore, even in a case where the substrate 100 has a hollow portion, it is possible to manufacture the light emitting device 10 with patterning easily.

The third end portion 105 and the fourth end portion 106 are edges of an inner periphery of the substrate 100. The third end portion 105 and the fourth end portion 106 are continuous to each other directly or through the other end portion. When seen in a direction perpendicular to the first surface 101 of the substrate 100, the third end portion 105 and the fourth end portion 106 may be parallel or non-parallel to each other. Further, each of the third end portion 105 and the fourth end portion 106 may be straight or curved. Both of the third end portion 105 and the fourth end portion 106 face the first area 108.

The substrate 100 includes the fifth end portion 107a and the fifth end portion 107b. The fifth end portion 107a and the fifth end portion 107b are edges of an outer periphery of the substrate 100. In the example in the present diagram, the fifth end portion 107a is an end portion on an opposite side to the third end portion 105 of the substrate 100, and the fifth end portion 107b is an end portion on an opposite side to the fourth end portion 106 of the substrate 100. The fifth end portion 107a and the fifth end portion 107b are continuous to each other directly or through the other end portion. When seen in a direction perpendicular to the first surface 101 of the substrate 100, the fifth end portion 107a and the fifth end portion 107b may be parallel or non-parallel to each other. Further, each of the fifth end portion 107a and the fifth end portion 107b may be straight or curved. Both of the fifth end portion 107a and the fifth end portion 107b face the external area 11.

The first end portion 103 connects the third end portion 105 and the fifth end portion 107a, and the second end portion 104 connects the fourth end portion 106 and the fifth end portion 107b. In addition, one end of the first end portion 103 and one end of the second end portion 104 are continuous through at least the third end portion 105 and the fourth end portion 106, and the other end of the first end portion 103 and the other end of the second end portion 104 are continuous through at least the fifth end portion 107a and the fifth end portion 107b. Both of the first end portion 103 and the second end portion 104 face the second area 109. All of the first end portion 103, the second end portion 104, the third end portion 105, the fourth end portion 106, the fifth end portion 107a, and the fifth end portion 107b form one closed area, and the area is equal to an area on which the substrate 100 exists.

A plurality of light emitting devices 10 according to the present example can be used in combination. Specifically, it is possible to connect light emitting devices 10 by passing the substrate 100 of one light emitting device 10 through the first area 108 of the other light emitting device 10. In this manner, it is possible to further enhance an overall design by using the plurality of light emitting devices 10.

In the example in the present diagram, a plurality of light emitting portions 140 are provided over the first surface 101 of the substrate 100. Specifically, the light emitting device 10 includes two segments of the light emitting portions 140. The plurality of light emitting portions 140 have the same shape as the substrate 100 as a whole. However, without being limited to the example in the present diagram, only one light emitting portion 140 may be provided over the first surface 101 of the substrate 100. In addition, the shape of the light emitting portion 140 may be different from the shape of the substrate 100 when seen in a direction perpendicular to the first surface 101.

In the example in the present diagram, the first electrode 110 is divided into a plurality of areas and the plurality of light emitting portions 140 are provided over the first surface 101 of the substrate 100, but the first electrode 110 maybe integral over the first surface 101. In this case, one light emitting portion 140 may be formed over the first surface 101. Further, in the example in the present diagram, although the first electrode 110 is formed for each of the light emitting portions 140, the first electrode 110 may be continuously formed over the plurality of light emitting portions 140. In the example in the present diagram, the organic layer 120 and the second electrode 130 are continuously formed over the plurality of light emitting portions 140. However, without being limited to the example in the present diagram, at least one of the organic layer 120 and the second electrode 130 may be formed for each of the light emitting portions 140.

With reference to FIG. 10, in the light emitting device 10 according to the present example, each of terminals formed over the substrate 100 will be described in detail below.

The light emitting device 10 according to the present example includes a first terminal 203a, a first terminal 203b, a first terminal 203c, a second terminal 204a, a second terminal 204b, a second terminal 204c, a terminal 206a, a terminal 206b, a terminal 207a, and a terminal 207b. The first terminal 203a, the first terminal 203b, and the first terminal 203c are provided in the first end portion 103 and are arranged along the end surface of the substrate 100. In addition, the second terminal 204a, the second terminal 204b, and the second terminal 204c are provided in the second end portion 104 and are arranged along the end surface of the substrate 100. The first end portion 103 and the second end portion 104 face each other. The first terminal 203a and the second terminal 204a face each other, the first terminal 203b and the second terminal 204b face each other, and the first terminal 203c and the second terminal 204c face each other. The first terminal 203a and the second terminal 204a are electrically connected to the second electrode 130, and the first terminal 203b, the second terminal 204b, the first terminal 203c, and the second terminal 204c are electrically connected to the first electrode 110. The first terminal 203a is disposed between the first terminal 203b and the first terminal 203c, and the second terminal 204a is disposed between the second terminal 204b and the second terminal 204c.

The terminal 206a and the terminal 206b are disposed between the light emitting portion 140 and the third end portion 105, and are adjacent to each other. In addition, the terminal 207a and the terminal 207b are disposed between the light emitting portion 140 and the fifth end portion 107a, and are adjacent to each other. The terminal 206a and the terminal 207a are electrically connected to the first electrode 110, and the terminal 206b and the terminal 207b are electrically connected to the second electrode 130.

In the present example, the first interconnect 191 is connected to the first terminal 203a, the first terminal 203b, and the first terminal 203c, and the second interconnect 192 is connected to the second terminal 204a, the second terminal 204b, and the second terminal 204c. That is, the first interconnect 191 includes a plurality of interconnects, and each of the interconnects of the first interconnect 191 is connected to the first terminal 203b and the first terminal 203c connected to the first electrode 110 and the first terminal 203a connected to the second electrode 130. In addition, the second interconnect 192 includes a plurality of interconnects, and each of the interconnects of the second interconnect 192 is connected to the second terminal 204b and the second terminal 204c connected to the first electrode 110 and the second terminal 204a connected to the second electrode 130.

Further, the terminal 206a and the terminal 206b are respectively connected to a plurality of interconnects included in the same interconnect (a flexible cable or the like not illustrated), and the terminals 207a and the terminal 207b are respectively connected to a plurality of interconnects included in the same interconnect (not illustrated).

The light emitting device 10 includes the conductive portion 170. The conductive portion 170 is electrically connected to the first electrode 110. When seen in a direction perpendicular to the first surface 101, at least a part of the conductive portion 170 overlaps the first electrode 110, and more preferably, the entire conductive portion 170 overlaps the first electrode 110. In addition, the conductive portion 170 is disposed between the light emitting portion 140 and the edge of the substrate 100. Specifically, when seen in a direction perpendicular to the first surface 101 of the substrate 100, the outer periphery of the light emitting portion 140 and the outer periphery of the substrate 100 are separated. The conductive portion 170 is disposed between the outer periphery of the light emitting portion 140 and the outer periphery of the substrate 100, and extends along the outer periphery of the light emitting portion 140 and the outer periphery of the substrate 100.

In the present example, the conductive portion 170 includes a conductive portion 170a and a conductive portion 170b. The conductive portion 170a is disposed between the fifth end portion 107a and the fifth end portion 107b facing the external area 11 in the outer periphery of the substrate 100 and the light emitting portion 140. The conductive portion 170b is disposed between the third end portion 105 and the fourth end portion 106 facing the first area 108 in the outer periphery of the substrate 100 and the light emitting portion 140.

In the example illustrated in the present diagram, the conductive portions 170 are formed one by one for one light emitting portion 140. Specifically, the conductive portion 170 is formed along one edge of the light emitting portion 140. However, without being limited to the present example, the conductive portions 170 may be formed on both sides of one light emitting portion 140.

The first terminal 203b and the second terminal 204b are disposed at both ends of the conductive portion 170a in an extending direction. In addition, the first terminal 203c and the second terminal 204c are disposed at both ends of the conductive portion 170b in an extending direction. The terminal 207a is connected to a middle portion of the conductive portion 170a, and is disposed in the fifth end portion 107a. The terminal 206a is connected to a middle portion of the conductive portion 170b, and is disposed in the third end portion 105.

At least a part of the second electrode 130 passes over the insulating film 150 and is connected to the first terminal 203a, the second terminal 204a, the terminal 206b, and the terminal 207b.

The first terminal 203a, the first terminal 203b, the first terminal 203c, the second terminal 204a, the second terminal 204b, the second terminal 204c, the terminal 206a, the terminal 206b, the terminal 207a, and the terminal 207b include at least one of a layer formed of the same material as the conductive portion 170 and a layer formed of the same material as the first electrode 110, for example. It is possible to form a layer formed of the same material as the conductive portion 170 among the first terminal 203a, the first terminal 203b, the first terminal 203c, the second terminal 204a, the second terminal 204b, the second terminal 204c, the terminal 206a, the terminal 206b, the terminal 207a, and the terminal 207b, by the same step as the conductive portion 170. For this reason, the conductive portion 170 may be integrated with at least a part of layers in the first terminal 203b, the first terminal 203c, the second terminal 204b, the second terminal 204c, the terminal 206a, and the terminal 207a.

Note that, the light emitting device 10 may not include at least any one of the first terminal 203a, the first terminal 203b, the first terminal 203c, the second terminal 204a, the second terminal 204b, the second terminal 204c, the terminal 206a, the terminal 206b, the terminal 207a, and the terminal 207b.

In the present example, the substrate 100 has a hollow heart shape as a whole. The hollowed portion is the first area 108. However, the shapes of the substrate 100 and the light emitting portion 140 are not limited to the present example, and may be a circle, a rectangle, a polygon, a star, or the like. However, it is preferable that at least a part of an edge of the light emitting portion 140 is along the edge of the substrate 100. In addition, the substrate 100 is not closed in a ring shape, and is interrupted at the second area 109 as described above.

Although the example embodiment and the examples are described with reference to the drawings, these are examples of the present invention, and various other configurations other than the example embodiment and the examples described above can be adopted.

This application claims priority based on Japanese Patent Application No. 2017-027600 filed on Feb. 17, 2017, the disclosure of which is incorporated herein in its entirety.

1. A light emitting device comprising:
a light emitting portion which is disposed on a first surface side of a substrate and has a laminated structure including a first electrode, an organic layer, and a second electrode;
a first terminal which is disposed over a first end portion of the substrate and is electrically connected to the first electrode or the second electrode;
a second terminal which is disposed over a second end portion, facing the first end portion, of the substrate and is connected to the first electrode or the second electrode;
a first interconnect which is connected to the first terminal to extend in a direction different from a direction toward the second end portion; and
a second interconnect which is connected to the second terminal to extend in a direction different from a direction toward the first end portion.

2. The light emitting device according to claim 1,
wherein at least one of the first interconnect and the second interconnect overlaps the light emitting portion on an opposite side to a light emitting surface side of the light emitting portion.

3. The light emitting device according to claim 1, further comprising:
a fixing member which is fixed to the substrate,
wherein at least one of the first interconnect and the second interconnect passes through an opening provided in the fixing member.

4. The light emitting device according to claim 1,
wherein the first terminal and the second terminal are electrically connected to the same electrode out of the first electrode and the second electrode.

5. The light emitting device according to claim 4, further comprising:
a third terminal which is electrically connected to an electrode different from the electrode, to which the first terminal and the second terminal are electrically connected, out of the first electrode and the second electrode.

6. The light emitting device according to claim 1,
wherein each of the first interconnect and the second interconnect is provided separately from the substrate.

7. The light emitting device according to claim 1,
wherein the substrate surrounds a first area when seen in a direction perpendicular to the substrate and the substrate is disconnected in a second area continuous to the first area, and the first end portion and the second end portion face each other through the second area.
